(19) United States
(12) Patent Application Publication
(10) Pub. No.: US 2026/0190590 A1
(43) Pub. Date: Jul. 2, 2026

(54) LIGHT-EMITTING SUBSTRATE, BACKLIGHT MODULE, AND DISPLAY APPARATUS

(71) Applicants: Hefei BOE Ruisheng Technology Co., Ltd., Hefei, Anhui (CN); BOE Technology Group Co., Ltd., Beijing (CN)

(72) Inventors: Yiding SUN, Beijing (CN); Amei CHENG, Beijing (CN); Kangli WANG, Beijing (CN); Bing ZHANG, Beijing (CN); Hai TANG, Beijing (CN); Liangliang XU, Beijing (CN); Qi QI, Beijing (CN)

(73) Assignees: Hefei BOE Ruisheng Technology Co., Ltd., Hefei, Anhui (CN); BOE Technology Group Co., Ltd., Beijing (CN)

(21) Appl. No.: 18/847,264

(22) PCT Filed: Sep. 22, 2023
(86) PCT No.: PCT/CN2023/120857

§ 371 Date: Sep. 16, 2024

(51) Int. Cl. H10H 29/856; H10H 29/49

(52) U.S. Cl. CPC H10H 29/856; H10H 29/49

(57) ABSTRACT

A light-emitting substrate includes a circuit board, an electronic component, a first reflective layer and a first bonding layer. The first reflective layer includes a hollow region and a first slit group. An orthogonal projection of the electronic component on the circuit board is located within an orthogonal projection of the hollow region on the circuit board. The first slit group includes first slits arranged at intervals. A sum of a length of a first slit and a length of a connection line between the first slit and another first slit adjacent to the first slit is a first length. A ratio of the first length to a perimeter of a first closed figure is in a range of 1/4 to 1/3. The first closed figure is composed of the first slits belonging to same first slit group that are connected end to end in a clockwise or counterclockwise direction.

### CROSS-REFERENCE TO RELATED APPLICATION

This application is a national phase entry under 35 USC 371 of International Patent Application No. PCT/CN2023/120857, filed on Sep. 22, 2023, which is incorporated herein by reference in its entirety.

### TECHNICAL FIELD

The present disclosure relates to the field of display technologies, and in particular, to a light-emitting substrate, a backlight module, and a display apparatus.

### BACKGROUND

With the development of light-emitting diode technologies, light-emitting substrates using light-emitting diodes (LEDs) with mini scale and even micro scale have been widely used. Therefore, a picture contrast of a product (e.g., a liquid crystal display (LCD)) using the light-emitting substrate may reach a level of an organic light-emitting diode (OLED) display product, and the product may retain the technical advantages of the liquid crystal display (LCD). As a result, the display effect of the picture may be improved, which may provide a good visual experience for users.

### SUMMARY

In an aspect, a light-emitting substrate is provided. The light-emitting substrate includes a circuit board, an electronic component, a first reflective layer and a first bonding layer. The electronic element and the first reflective layer are disposed on the circuit board. The first bonding layer is disposed on a surface of the first reflective layer close to the circuit board. The first reflective layer includes a hollow region and a first slit group arranged around the hollow region; an orthogonal projection of the electronic component on the circuit board is located within an orthogonal projection of the hollow region on the circuit board; the first slit group includes a plurality of first slits arranged at intervals.

A sum of a length of a first slit and a length of a connection line between the first slit and another first slit adjacent to the first slit is a first length; a ratio of the first length to a perimeter of a first closed figure is in a range of 1/4 to 1/3; and the first closed figure is composed of the plurality of first slits belonging to the same first slit group that are connected end to end in a clockwise or counterclockwise direction.

In some embodiments, a ratio of the length of the first slit to the length of the connection line between the first slit and the another first slit adjacent to the first slit is in a range of 2 to 3.

In some embodiments, the first reflective layer includes a plurality of first slit groups, and at least two first slit groups are arranged around a same hollow region.

In some embodiments, geometric centers of at least two first closed figures corresponding to the at least two first slit groups arranged around the same hollow region coincide with a geometric center of the hollow region.

In some embodiments, a distance between two first closed figures corresponding to any two adjacent first slit groups is a first distance; among the at least two first slit groups arranged around the same hollow region, a distance between a first slit group closest to the hollow region and the hollow region is a second distance; and the first distance is substantially equal to the second distance.

In some embodiments, a distance between two first closed figures corresponding to any two adjacent first slit groups is greater than or equal to 0.5 mm.

In some embodiments, along a first direction, a connection line between two adjacent first slits in any first slit group is arranged opposite to a first slit in at least one first slit group, the first direction being perpendicular to a boundary of the hollow region and parallel to a plane where the circuit board is located.

In some embodiments, among two adjacent first slit groups, a length of a first slit in any one first slit group is greater than or equal to a length of a connection line between two adjacent first slits in any one first slit group.

In some embodiments, an outer boundary of the orthogonal projection of the hollow region on the circuit board is a second closed figure; and the first closed figure and the second closed figure are similar.

In some embodiments, the first closed figure is in a shape of any one of a circle, an ellipse and a polygon, and the second closed figure is in a shape of any one of a circle, an ellipse and a polygon.

In some embodiments, a plurality of electronic components include a plurality of light-emitting devices, and the plurality of light-emitting devices are arranged in a plurality of rows and a plurality of columns. The first reflective layer includes a central region and an edge region surrounding the central region. The first reflective layer further includes a second slit group disposed in the edge region, the second slit group includes a plurality of second slits arranged at intervals, and the plurality of second slits are located between two adjacent rows of light-emitting devices or two adjacent columns of light-emitting devices.

In some embodiments, a ratio of a length of a second slit to a length of a connection line between the second slit and another second slit adjacent to the second slit is in a range of 2 to 3.

In some embodiments, the first reflective layer includes a plurality of second slit groups, and the plurality of second slit groups are divided into a plurality of row slit groups and a plurality of column slit groups; and a row slit group is located between two adjacent rows of light-emitting devices, and a column slit group is located between two adjacent columns of light-emitting devices.

In some embodiments, the first reflective layer has a first axis extending in a row direction and a second axis extending in a column direction, the plurality of row slit groups are symmetrical about the first axis, and the plurality of column slit groups are symmetrical about the second axis.

In some embodiments, a distance between two ends far away from each other of second slits that are located at two ends of the second slit group is greater than or equal to a distance between two ends far away from each other of an adjacent row or column of hollow regions located in the edge region.

In some embodiments, along a second direction, a connection line between two adjacent second slits in any second slit group is arranged opposite to a second slit in at least one second slit group, the second direction being perpendicular to the second slits in the second slit group.

In some embodiments, among two adjacent second slit groups, a length of a second slit in any one second slit group is greater than or equal to a length of a connection line between two adjacent second slits in any one second slit group.

In some embodiments, distances between the second slit group and two adjacent rows or columns of hollow regions are substantially equal.

In some embodiments, a radial length of a figure enclosed by a boundary line between the edge region and the central region is greater than or equal to 300 mm.

In another aspect, a backlight module is provided. The backlight module includes: the light-emitting substrate as described in any of the above embodiments and a plurality of optical films. The light-emitting substrate has a light-exit side and a non-light-exit side opposite to each other, and the plurality of optical films are disposed on the light-exit side of the light-emitting substrate.

In yet another aspect, a display apparatus is provided. The display apparatus includes the backlight module as described in any one of the above embodiments, and a display panel disposed on a side of the plurality of optical films in the backlight module away from the light-emitting substrate.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of another display apparatus, in accordance with some embodiments;

FIG. 3 is a sectional view of a display apparatus, in accordance with some embodiments;

FIG. 4 is a circuit diagram of a light-emitting substrate, in accordance with some embodiments;

FIG. 5 is a schematic diagram of interference between a first reflective layer and an electronic component, in accordance with some embodiments;

FIG. 6 is a schematic diagram of cracking in an encapsulation portion, in accordance with some embodiments;

FIG. 7 is a top view of a light-emitting substrate, in accordance with some embodiments;

FIG. 8 is a partially enlarged view of a hollow region of a light-emitting substrate, in accordance with some embodiments;

FIG. 9 is a partial enlarged view of a hollow region of a light-emitting substrate, in accordance with some other embodiments;

FIG. 10 is a sectional view taken along the section line A-A′ in FIG. 8;

FIG. 11 is a partial enlarged view of a first reflective layer, in accordance with some embodiments;

FIG. 12 is a top view of a first reflective layer, in accordance with some embodiments;

FIG. 13 is a top view of another first reflective layer, in accordance with some embodiments;

FIG. 14 is a top view of yet another first reflective layer, in accordance with some embodiments; and

FIG. 15 is a top view of yet another first reflective layer, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

In the description of some embodiments, the terms such as “coupled” and “connected” and derivatives thereof may be used. The term “connected” shall be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of regions in a device, and are not intended to limit the scope of the exemplary embodiments.

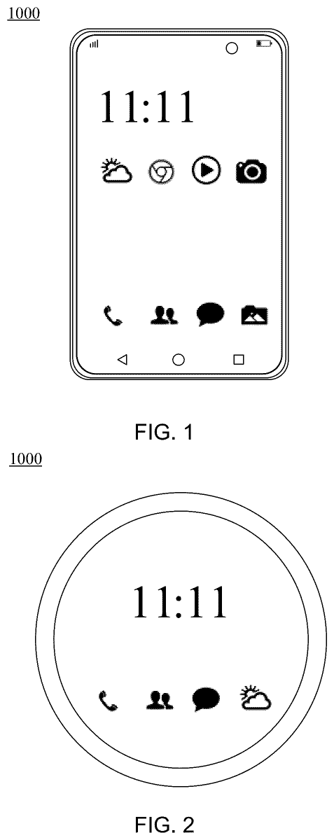

As shown in FIG. 1, some embodiments of the present disclosure provide a display apparatus 1000. The display apparatus 1000 may be any apparatus that displays an image whether in motion (e.g., a video) or stationary (e.g., a still image), and whether textual or graphical.

For example, referring to FIGS. 1 and 2, the display apparatus 1000 may be any product or component having a display function, such as a television, a notebook computer, a tablet computer, a mobile phone, a personal digital assistant (PDA), a navigator, a wearable device, a virtual reality (VR) device.

For example, as shown in FIG. 1, the display apparatus 1000 may be a portable display product. For example, the display apparatus 1000 may be a mobile phone shown in FIG. 1. As another example, referring to FIG. 2, the display apparatus 1000 may be a wearable device. For example, the display apparatus 1000 may be a watch shown in FIG. 2.

It will be noted that, depending on different application scenarios, a shape of a display surface of the display apparatus 1000 varies. The shape of the display surface of the display apparatus 1000 may be any one of a circle, an ellipse, a polygon or an irregular shape, which is not specifically limited in the embodiments of the present disclosure.

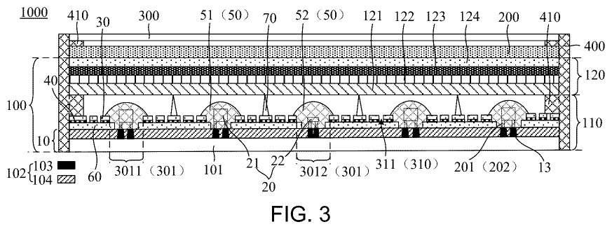

In some embodiments, referring to FIG. 3, the display apparatus 1000 may be a liquid crystal display (LCD) apparatus.

For example, referring to FIG. 3, the display apparatus 1000 includes a backlight module 100, a display panel 200 and a cover plate 300. The display panel 200 is disposed on a side of the backlight module 100 from which light is emitted. The cover plate 300 is disposed on a side of the display panel 200 away from the backlight module 100.

Referring to FIG. 3, the backlight module 100 includes a light-emitting substrate 110, and the light-emitting substrate 110 has a light-exit side and a non-light-exit side that are opposite to each other. The light-exit side refers to a side of the light-emitting substrate 110 from which light is emitted (an upper side of the light-emitting substrate 110 in FIG. 3), and the non-light-exit side refers to another side opposite to the light-exit side (a lower side of the light-emitting substrate 110 in FIG. 3). The display panel 200 is disposed on the light-exit side of the light-emitting substrate 110.

In some embodiments, referring to FIG. 3, the backlight module 100 further includes a plurality of optical films 120, and the plurality of optical films 120 are located on the light-exit side of the light-emitting substrate 110.

The light emitted from the light-emitting substrate 110 passes through the optical films 120 and then is directed to the display panel 200. That is, the display panel 200 is disposed on a side of the optical films 120 away from the light-emitting substrate 110. It will be noted that the optical films 120 modulate a wavelength of light emitted by the light-emitting substrate 110 and/or modulate a propagation direction of light.

As shown in FIG. 3, the light-emitting substrate 110 may directly emit white light. After the white light passes through the plurality of optical films 120, the propagation direction of the white light is modulated and then is directed to the display panel 200. Alternatively, the light-emitting substrate 110 may emit light of other colors (e.g., blue light), which is then directed to the display panel 200 after the plurality of optical films 120 modulate the wavelength of light and/or the propagation direction.

For example, referring to FIG. 3, the plurality of optical films 120 include a scattering layer 121, a color conversion layer 122, a diffusion sheet 123 and a composite film 124. The scattering layer 121, the color conversion layer 122, the diffusion sheet 123 and the composite film 124 may be, for example, sequentially arranged away from the display panel 200. That is, the diffusion sheet 123 may be disposed on the light-exit side of the light-emitting substrate 110; the composite film 124 is disposed on a side of the diffusion sheet 123 away from the light-emitting substrate 110; the scattering layer 121 and the color conversion layer 122 are disposed on a side of the diffusion sheet 123 close to the light-emitting substrate 110; and the display panel 200 is disposed on a side of the composite film 124 away from the light-emitting substrate 110.

The scattering layer 121 is capable of blurring the light emitted by the light-emitting substrate 110 and providing support for the color conversion layer 122, the diffusion sheet 123 and the composite film 124. Due to excitation of light of a certain color emitted by the light-emitting substrate 110, the color conversion layer 122 may convert the light into white light, so as to improve the utilization efficiency of light energy of the light-emitting substrate 110. The diffusion sheet 123 is capable of uniformizing the light passing through the diffusion sheet 123. The composite film 124 is capable of improving the light extraction efficiency of the light-emitting substrate 110, thereby increasing the display brightness of the display apparatus 1000.

It will be noted that the composite film 124 may include a brightness enhancement film (BEF) and a dual brightness enhancement film (DBEF), which increases the light flux within a certain angle range based on the principles of total reflection, refraction and polarization and in turn improves the brightness of the display apparatus 1000.

For example, as shown in FIG. 3, the light-emitting substrate 110 emits blue light. The color conversion layer 122 may include a red quantum dot material, a green quantum dot material, and a transparent material. When the blue light emitted by the light-emitting substrate 110 passes through the red quantum dot material, the blue light is converted into red light. When the blue light passes through the green quantum dot material, the blue light is converted into green light. The blue light may directly pass through the transparent material. Then, the blue light, red light and green light are mixed and superimposed in a certain proportion to present white light. Next, the scattering layer 121 and the diffusion sheet 123 modulate incident light in different propagation directions and emit the light in a uniform state, so as to ameliorate light shadow produced by the light-emitting substrate 110 and enhance the display quality of the display apparatus 1000.

In some embodiments, referring to FIG. 3, the display apparatus 1000 further includes a support frame 400, and the support frame 400 surrounds a periphery of the light-emitting substrate 110 for protection. Furthermore, two support protrusions 410 are provided on the support frame 400. One support protrusion 410 is located between the display panel 200 and the cover plate 300, and another support protrusion 410 is located between the optical film 120 and the light-emitting substrate 110, so as to provide support for the cover plate 300 and the optical film 120.

In some embodiments, referring to FIG. 3, the light-emitting substrate 110 includes a circuit board 10, a plurality of electronic components 20 and a first reflective layer 30.

In some examples, referring to FIG. 3, the circuit board 10 may be an FR-4 printed circuit board (PCB), or may be a flexible PCB that is easily deformed. For example, a material of the circuit board 10 may include one or more ceramic materials such as silicon nitride, AlN and Al₂O₃, or may include metal or metal compound, such as metal core PCB or metal copper clade laminate (MCCL).

In some examples, referring to FIGS. 3 and 10, the circuit board 10 may include a substrate 101 and a circuit layer 102, the circuit layer 102 is disposed on the substrate 101, and the circuit layer 102 includes at least one conductive layer 103 and at least one insulating layer 104. For example, as shown in FIG. 10, the circuit layer 102 includes a first insulating layer 1041, a second insulating layer 1042 and a first conductive layer 1031. The first insulating layer 1041 is located between the first conductive layer 1031 and the substrate 101 to play an insulating and buffering role. The second insulating layer 1042 is located on a side of the first conductive layer 1031 away from the substrate 101 to play a role of insulating and anti-oxidation.

As shown in FIG. 3, the substrate 101 may be a rigid substrate or a flexible substrate. A material of the rigid substrate includes at least one of glass, quartz, sapphire, ceramic or polymethyl methacrylate (PMMA). A material of the flexible substrate includes at least one of epoxy resin, triazine, silicone resin or polyimide. A material of the conductive layer 103 includes at least one of copper, molybdenum-niobium alloy, nickel or indium tin oxide.

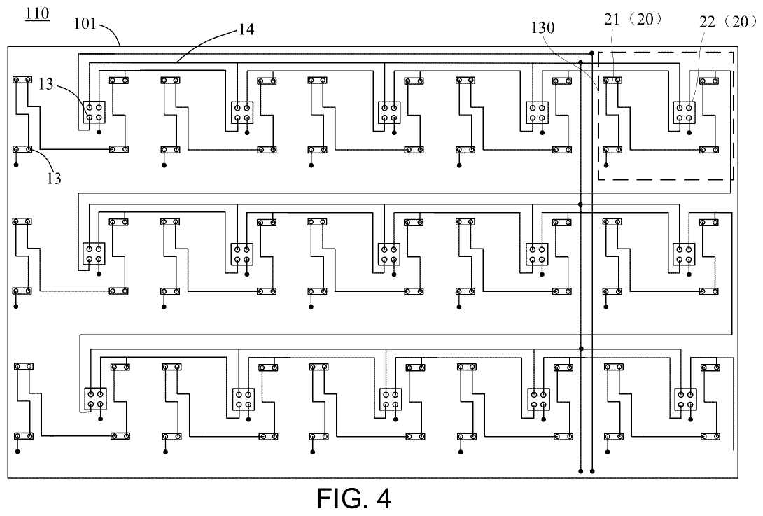

As shown in FIGS. 3 and 4, the circuit board 10 includes pads 13 and circuit wires 14. The circuit wires 14 are connected to the pads 13 for transmitting circuit signals. The electronic component 20 may be fixed on the circuit board 10 through pads 13 and electrically connected to the circuit board 10. Referring to FIG. 10, the pads 13 may be, for example, portions of the first conductive layer 1031 exposed by the second insulating layer 1042.

In some examples, as shown in FIGS. 3 and 4, the plurality of electronic components 20 are disposed on the circuit board 10. The electronic component 20 has a pin structure 201 connected to an external circuit structure (such as pads 13). For example, the electronic component 20 may be electrically connected to the circuit board 10 by soldering the pin structure 201 to the pad 13 through solder S, so as to receive a driving signal. It will be noted that the pin structure 201 is usually made of metal or alloy material with good conductivity.

For example, as shown in FIGS. 3 and 4, the electronic components 20 may include light-emitting devices 21 and microchips 22. The pin structure 201 of a light-emitting device 21 may include, for example, two pins 202, and the two pins 202 are respectively connected to two pads 13. The pin structure 201 of a microchip 22 may include, for example, four pins 202, and the four pins 202 are respectively connected to four pads 13.

It will be noted that the pin structure 201 of a microchip 22 may also include eight pins 202 or ten pins 202, which may be determined according to the actual circuit design and will not be specifically limited in the embodiments of the present disclosure.

As shown in FIGS. 3 and 4, the light-emitting devices 21 may include micro light-emitting diodes (micro LEDs) and/or mini light-emitting diodes (mini LEDs).

It will be noted that a size (e.g., a length) of the micro LED is less than 50 micrometers, for example, in a range of 10 micrometers to 50 micrometers. A size (e.g., a length) of the mini LED is in a range of 50 micrometers to 150 micrometers, for example, in a range of 80 micrometers to 120 micrometers.

As shown in FIGS. 3 and 4, the microchips 22 may include sensor chips and/or driver chips. The sensor chip may be, for example, a photosensitive sensor chip or a thermosensitive sensor chip. A driver chip is used for providing driving signals for light-emitting devices 21.

In some examples, as shown in FIG. 3, the first reflective layer 30 is disposed on the circuit board 10. The first reflective layer 30 is configured to reflect light emitted from the light-emitting devices 21 toward the circuit board 10, so that more light emitted by the light-emitting devices 21 is directed toward the display panel 200. Therefore, the light extraction efficiency of the light-emitting substrate 110 is improved, and the display effect is improved.

It will be noted that a material of the first reflective layer 30 includes polyester material, and the polyester material may be doped with reflective ions. For example, the material of the first reflective layer 30 includes polymer obtained by polycondensation of polyol and polyacid. For example, the material of the first reflective layer 30 includes at least one of linear thermoplastic resins such as polyethylene terephthalate, polybutylene terephthalate and polyarylate.

The first reflective layer 30 is connected to the circuit board 10 through a bonding process. That is, the light-emitting substrate 110 further includes a first bonding layer 40, and the first bonding layer 40 is disposed on a surface of the first reflective layer 30 close to the circuit board 10, so that the first reflective layer 30 is attached and fixed on the circuit board 10. It will be noted that an orthogonal projection of the first bonding layer 40 on the circuit board 10 substantially overlaps with an orthogonal projection of the first reflective layer 30 on the circuit board 10.

In some embodiments, referring to FIGS. 3, 5 and 6, the first reflective layer 30 is provided therein with a plurality of hollow regions 301, and an orthogonal projection of the electronic component 20 on the circuit board 10 is located within an orthogonal projection of the hollow region 301 on the circuit board 10. For example, an electronic component 20 is located in a hollow region 301 and is connected to pads 13 through a pin structure 201.

It will be noted that an outer boundary of the orthogonal projection of the hollow region 301 on the circuit board 10 is a second closed figure S2, and the second closed figure S2 is substantially in a shape of any one of an ellipse, a circle and a polygon. Some embodiments of the present disclosure will be illustrated below by taking an example in which the second closed figure S2 is substantially in a shape of a circle, but the implementation manners of the present disclosure are not limited thereto.

Herein, the term “substantially in a shape of a circle or an ellipse” means in a shape of a circle or an ellipse as a whole, but is not limited to a standard circle or ellipse. That is, “circle or ellipse” herein includes not only a substantial circle or ellipse but also a shape similar to a circle or ellipse. For example, a part of a boundary of a circle or ellipse is a straight line.

Herein, the term “substantially in a shape of a polygon” means in a shape of a polygon as a whole, but is not limited to a standard polygon. That is, “polygon” herein includes not only a standard polygon but also a shape similar to a polygon. For example, corners of the polygon are curved, that is, the corners are smooth, and the shape is a polygon with rounded corners.

A maximum radial dimension of the hollow region 301 is less than or equal to 2.5 mm. For example, the orthogonal projection of the hollow region 301 on the circuit board 10 is substantially in a shape of a circle, and a diameter of the hollow region 301 is in a range of 1.4 mm to 2.2 mm. For example, the diameter of the hollow region 301 is any one of 1.4 mm, 1.5 mm, 1.6 mm, 1.8 mm, 2 mm, 2.1 mm, and 2.2 mm.

In this case, an aperture of the hollow region 301 is relatively small, so that more light emitted by the light-emitting device 21 may be directed toward the display panel 200. Thus, the light extraction efficiency of the light-emitting substrate 110 is improved, and the display effect is improved.

It will be understood that shapes of hollow regions 301 corresponding to different electronic components 20 may be the same or different; and areas of hollow regions 301 corresponding to different electronic components 20 may be equal or unequal.

For example, referring to FIGS. 3, 5 and 6, the electronic components 20 include light-emitting devices 21 and microchips 22, and the hollow regions 301 include first hollow regions 3011 and second hollow regions 3012. The orthogonal projection of the light-emitting device 21 on the circuit board 10 is located within an orthogonal projection of the first hollow region 3011 on the circuit board 10, and an orthogonal projection of the microchip 22 on the circuit board 10 is located within an orthogonal projection of the second hollow region 3012 on the circuit board 10.

On this basis, an area of a hollow region 301 may be, for example, positively correlated with an area of a corresponding electronic component 20; and a shape of the hollow region 301 may be, for example, similar to a shape of a contour of an orthogonal projection of the corresponding electronic component 20 on the circuit board 10.

For example, the shape of the first hollow region 3011 is similar to the shape of the contour of the orthogonal projection of the light-emitting device 21 on the circuit board 10; and the shape of the second hollow region 3012 is similar to the shape of the contour of the orthogonal projection of the microchip 22 on the circuit board 10.

Some embodiments of the present disclosure will be illustrated below by taking an example in which the first hollow region 3011 and the second hollow region 3012 are both circular and have equal areas, but the implementation manners of the present disclosure are not limited thereto.

In some embodiments, as shown in FIGS. 3, 5 and 6, the light-emitting substrate 110 further includes a plurality of encapsulation portions 50 arranged at intervals, and an encapsulation portion 50 encapsulates at least one electronic component 20 to protect the electronic component 20, which is conducive to improving the water resistance and corrosion resistance of the light-emitting substrate 110 and improving the light extraction efficiency of the light-emitting substrate 110. Moreover, an encapsulation portion 50 may, for example, cover a hollow region 301. That is, the orthogonal projection of the hollow region 301 on the circuit board 10 is located within an orthogonal projection of the encapsulation portion 50 on the circuit board 10.

It will be noted that the encapsulation portion 50 may be formed through spraying high thixotropic glue on the electronic component 20 by a dispenser and then a curing process. In addition, the encapsulation portion 50 may be in a shape of a spherical cap or a semi-ellipsoidal sphere, which is not specifically limited in the embodiments of the present disclosure.

It will be understood that the material of the encapsulation portion 50 is adaptively adjusted for different types of electronic components 20. For example, the electronic components 20 are optical components, and the encapsulation portions 50 are made of a transparent material. The electronic components 20 are non-optical components, and the material of the encapsulation portion 50 has no requirements on light transmittance, which may be a transparent material, a reflective material, or a light-absorbing material.

It will be noted that the transparent material may include transparent silicone; the reflective material may include at least one of white ink, white resin or silicon-based white glue; and the light-absorbing material may include at least one of black ink, black resin or silicon-based black glue.

For example, referring to FIGS. 3, 5 and 6, the electronic components 20 include light-emitting devices 21 and microchips 22, and the encapsulation portions 50 include first encapsulation portions 51 and second encapsulation portions 52. The first encapsulation portion 51 encapsulates the light-emitting device 21 and the second encapsulation portion 52 encapsulates the microchip 22.

On this basis, the first encapsulation portions 51 may be, for example, made of a transparent material. The second encapsulation portions 52 and the first encapsulation portion 51 may be made of the same material, so that the first encapsulation portions 51 and the second encapsulation portions 52 may be formed simultaneously to reduce the process steps and simplify the process flow. The second encapsulation portions 52 and the first encapsulation portions 51 may also be made of different materials. The second encapsulation portions 52 may be, for example, made of a reflective material or a light-absorbing material.

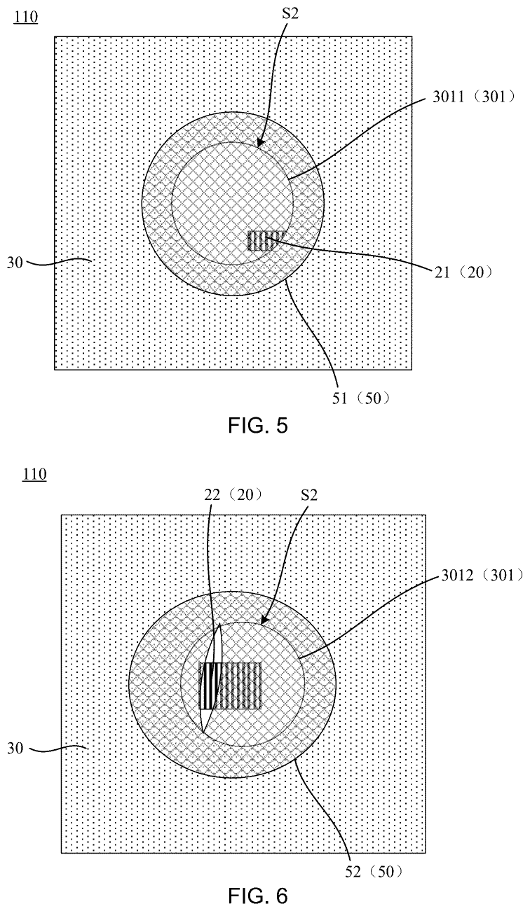

However, in the related art, a curing process is required for forming the encapsulation portion. The temperature of the curing process is in a range of 100° C. to 170° C. The first reflective layer will create shrinkage stress at this temperature. When the shrinkage stress of the first reflective layer is greater than the bonding force between the first bonding layer and the circuit board, the first reflective layer shrinks, resulting in the first reflective layer interfering with the electronic components (see FIG. 5) and/or cracking in the encapsulation portion (see FIG. 6), which leads to the reduced reliability or even failure of the electronic components. Thus, the product yield is reduced.

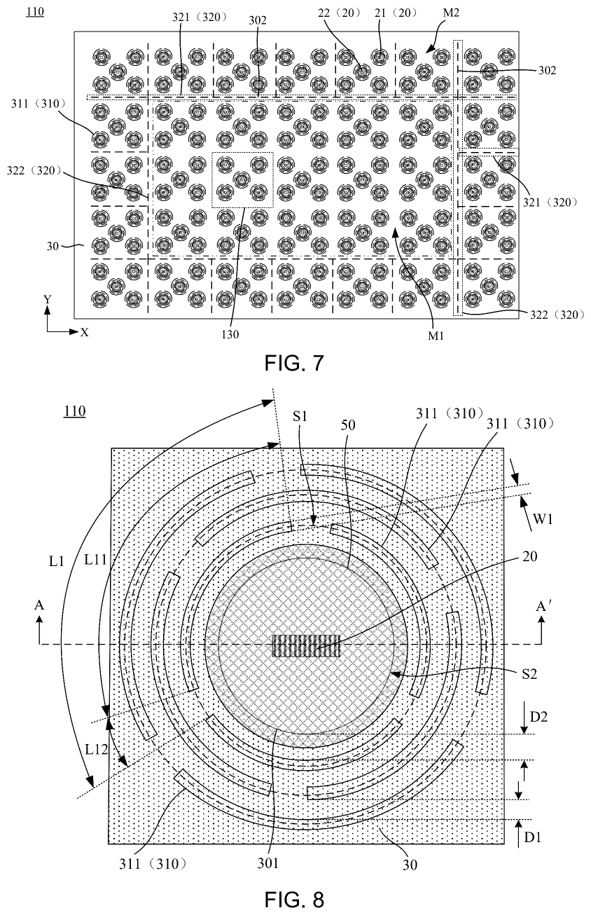

In light of this, as shown in FIGS. 7 to 10, in the light-emitting substrate 110 provided in some embodiments of the present disclosure, the first reflective layer 30 further includes a first slit group 310 arranged around the hollow region 301, and the first slit group 310 includes a plurality of first slits 311 arranged at intervals.

It will be noted that an orthogonal projection of the encapsulation portion 50 on the circuit board 10 may, for example, be located within an orthogonal projection of the first slit group 310 on the circuit board 10. In this way, when the first reflective layer 30 shrinks at the first slit 311, no encapsulation portion 50 exists on the first slit 311, and the encapsulation portion 50 will not be subjected to the shrinkage stress in two opposite directions, thereby preventing the encapsulation portion 50 from cracking at the first slit 311.

In this case, when the shrinkage stress of the first reflective layer 30 is greater than the bonding force between the first bonding layer 40 and the circuit board 10, the first reflective layer 30 may shrink at the first slit 311 to release the stress, so that the tendency of relative motion of the first reflective layer 30 to the circuit board 10 at the hollow region 301 is weakened. Therefore, the shrinkage amount of the first reflective layer 30 at the hollow region 301 is reduced, the risk of the first reflective layer 30 interfering with the electronic component 20 and the cracking in the encapsulation portion 50 is reduced, the risk of failure of the electronic component 20 is reduced, and the product yield is improved.

In addition, since the first reflective layer 30 shrinks at the first slit 311 to release stress, it may be possible to reduce the shrinkage amount of an edge of each hollow region 301 of the first reflective layer 30 toward the center of the first reflective layer 30, reduce the displacement accumulation of the edge of the first reflective layer 30, and disperse the tension of the first reflective layer 30 on the circuit board 10, and in turn reduce the stretching of the first reflective layer 30 on the circuit board 10 and reduce the warpage of the circuit board 10 (light-emitting substrate 110).

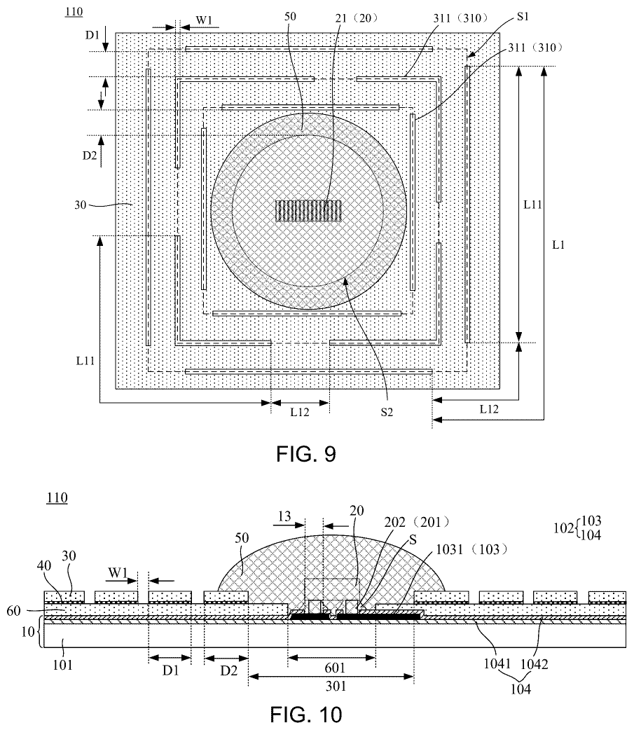

As shown in FIGS. 8 and 9, the first slit 311 is substantially in a shape of a rectangle, “L”, or a fan ring. Some embodiments of the present disclosure will be illustrated below by taking an example in which the first slit 311 is substantially in a shape of a fan ring. However, the implementation manners of the present disclosure are not limited thereto. In addition, it may also be considered that the shape of the first slit 311 is substantially rectangular, as long as the same technical idea is applied.

Herein, “substantially in a shape of a rectangle, ”L“, or a fan ring” means in a shape of a rectangle, “L”, or a fan ring as a whole, but is not limited to a standard shape of a rectangle, “L”, or fan ring. That is, “a shape of a rectangle, ”L“, or fan ring” herein includes not only a standard shape of a rectangle, “L”, or fan ring, but also a shape similar to a rectangle, “L”, or fan ring in consideration of process conditions. For example, corners or short sides of a rectangle are curved. For example, a corner or short side of “L” are curved. For another example, corners or short sides of a fan ring are curved.

It will be understood that, the longer the length L11 of the first slit 311 is, the better the stress release effect is. The longer the length L12 of the connection line of two adjacent first slits 311 is, the smaller the risk of the first reflective layer 30 being broken is.

Based on this, referring to FIGS. 8 and 9, a sum of a length L11 of a first slit 311 and a length L12 of a connection line between the first slit 311 and another first slit 311 adjacent to the first slit 311 is a first length L1, and a ratio of the first length L1 to a perimeter of the first closed figure S1 is in a range of 1/4 to 1/3.

It will be noted that the first closed figure S1 is composed of a plurality of first slits 311 belonging to the same first slit group 310 that are sequentially connected end to end in a clockwise or counterclockwise direction. The first closed figure is substantially in a shape of any one of a circle, an ellipse and a polygon.

Herein, referring to FIGS. 8 and 9, the length L11 of the first slit 311 is an average length of the first slit 311 along an extending direction of the first slit 311, and the length L12 of the connection line between the first slit 311 and another first slit 311 adjacent to the first slit 311 is an average length of the connection line along an extending direction of the connection line.

For example, as shown in FIG. 8, the first slit 311 is substantially in a shape of a fan ring, the length of the first slit 311 is an average of an inner arc length and an outer arc length of the fan ring; and the length L12 of the connection line between the first slit 311 and another first slit 311 adjacent to the first slit 311 is an average arc length of an arc connecting inner arcs of two adjacent fan rings along the extending direction and an arc connecting outer arcs of the two adjacent fan rings along the extending direction.

For example, referring to FIG. 9, at least one first slit 311 is substantially in a shape of a rectangle, the length L11 of the first slit 311 is a length of a long side of the rectangle, the length L12 of the connection line between the first slit 311 and another first slit 311 adjacent to the first slit 311 is a length of a connection line between two adjacent rectangles, and the connection line may be L-shaped.

For example, referring to FIG. 9, at least one first slit 311 is substantially in a shape of “L”, the length L11 of the first slit 311 is a length of an L-shaped side of the “L”, and the length L12 of the connection line between the first slit 311 and another first slit 311 adjacent to the first slit 311 is a length of a connection line between two adjacent “L”.

In the case where the ratio of the first length L1 to the perimeter of the first closed figure S1 is in a range of 1/4 to 1/3, by designing a ratio of the length of the first slit 311 to the length of the connection line of two adjacent first slits 311, it may be possible to realize good stress release effect on the premise of avoiding the first reflective layer 30 from breaking.

For example, referring to FIGS. 8 and 9, the ratio of the length L11 of the first slit 311 to the length L12 of the connection line between another first slit 311 adjacent to the first slit 311 is in a range of 2 to 3. In this case, the structural strength between two adjacent first slits 311 is relatively large, the risk of the first reflective layer 30 being broken is relatively low, and the stress release effect of the plurality of first slits 311 in the first slit group 310 is relatively good. In this way, the shrinkage amount at the hollow region 301 of the first reflective layer 30 may be greatly reduced without breaking the first reflective layer 30, thereby avoiding the first reflective layer 30 interfering with the electronic component 20 and the cracking in the encapsulation portion 50. In addition, the shrinkage amount of the edge of the first reflective layer 30 toward the center is greatly reduced, and the warpage of the circuit board 10 (the light-emitting substrate 110) is reduced.

For example, as shown in FIGS. 8 and 9, the length L11 of the first slit 311 is in a range of 1 mm to 3.5 mm. For example, the length L11 of the first slit 311 is any one of 1 mm, 1.2 mm, 1.4 mm, 1.5 mm, 1.8 mm, 2 mm, 2.3 mm, 2.5 mm, 2.6 mm, 2.8 mm, 3 mm, 3.1 mm, 3.2 mm, 3.4 mm, and 3.5 mm.

For example, as shown in FIGS. 8 and 9, the length L12 of the connection line between the first slit 311 and another first slit 311 adjacent to the first slit 311 is in a range of 0.5 mm to 1.5 mm. For example, the length L12 of the connection line between the first slit 311 and another first slit 311 adjacent to the first slit 311 is any one of 0.5 mm, 0.6 mm, 0.7 mm, 0.8 mm, 0.9 mm, 1 mm, 1.1 mm, 1.2 mm, 1.3 mm, 1.4 mm, and 1.5 mm.

In addition, referring to FIGS. 8, 9 and 10, the larger the width W1 of the first slit 311 is, the better the stress release effect is. The smaller the width W1 of the first slit 311 is, the lower the risk of the first reflective layer 30 being broken is.

Based on this, referring to FIGS. 8, 9 and 10, the width W1 of the first slit 311 is in a range of 0.05 mm to 0.2 mm. For example, the width W1 of the first slit 311 is any one of 0.05 mm, 0.06 mm, 0.07 mm, 0.08 mm, 0.1 mm, 0.11 mm, 0.12 mm, 0.14 mm, 0.15 mm, 0.17 mm and 0.2 mm, so as to realize a good stress release effect without breaking the first reflective layer 30.

In some embodiments, as shown in FIGS. 8 and 9, the first closed figure S1 and the second closed figure S2 may be similar. In this case, in an arbitrary direction parallel to a plane where the circuit board 10 is located, a distance between the first closed figure S1 and the second closed figure S2 may be substantially equal. In this way, the shrinkage stress on a portion of the first reflective layer 30 located between the first closed figure S1 and the second closed figure S2 is evenly dispersed, thereby preventing the portion of the first reflective layer 30 located between the first closed figure S1 and the second closed figure S2 from being locally subjected to excessive shrinkage stress and causing breakage.

It will be noted that the plane where the circuit board 10 is located refers to a plane where a surface of the circuit board 10 away from the first reflective layer 30 is located.

In some embodiments, as shown in FIGS. 8 and 9, the first reflective layer 30 includes a plurality of first slit groups 310, and at least two first slit groups 310 are disposed around the same hollow region 301. In this way, there are a plurality of stress release regions on a periphery of each hollow region 301. In this way, the first reflective layer 30 may release stress in sequence through the plurality of stress release regions on the periphery of the hollow region 301, thereby further reducing the shrinkage amount of the first reflective layer 30 at the hollow region 301, further reducing the risk of the first reflective layer 30 interfering with the electronic component 20 and the cracking in the encapsulation portion 50, further reducing the risk of failure of the electronic component 20, and in turn improving the product yield.

On this basis, referring to FIGS. 8, 9 and 10, a distance between two first closed figures S1 corresponding to any two adjacent first slit groups 310 surrounding the same hollow region 301 is a first distance D1. The first distance D1 is greater than or equal to 0.5 mm to reduce the risk of the first reflective layer 30 being broken. For example, as shown in FIGS. 8, 9 and 10, the first distance D1 is in a range of 0.5 mm to 2 mm. For example, the first distance D1 is any one of 0.5 mm, 0.8 mm, 1 mm, 1.2 mm, 1.5 mm, 1.7 mm, and 2 mm.

In addition, as shown in FIGS. 8 and 9, geometric centers of at least two first closed figures S1 corresponding to at least two first slit groups 310 arranged around the same hollow region 301 coincide with a geometric center of the hollow region 301. For example, geometric centers of first closed figures S1 corresponding to all first slit groups 310 arranged around the same hollow region 301 coincide with the geometric center of the hollow region 301.

In this case, the distance D1 between two first closed figures S1 corresponding to any two adjacent first slit groups 310 surrounding the same hollow region 301 is substantially equal. The shrinkage stress on a portion of the first reflective layer 30 located between two adjacent first slit groups 310 is evenly dispersed, thereby preventing the portion of the first reflective layer 30 located between two adjacent first slit groups 310 from being locally subjected to excessive shrinkage stress and causing breakage.

In some embodiments, as shown in FIGS. 8, 9 and 10, among the at least two first slit groups 310 arranged around the same hollow region 301, a distance between a first slit group 310 closest to the hollow region 301 and the hollow region 301 is a second distance D2. The first distance D1 and the second distance D2 are substantially equal, so as to reduce the number of parameters involved in the process of fabricating the first slits 311 and reduce the process difficulty.

In some embodiments, as shown in FIGS. 8 and 9, along a first direction, a connection line between two adjacent first slits 311 in any first slit group 310 is arranged opposite to a first slit 311 in at least one first slit group 310. For example, among two adjacent first slit groups 310, a connection line between two adjacent first slits 311 in one first slit group 310 is arranged opposite to a first slit 311 in the other first slit group 310. The first direction is perpendicular to a boundary of the hollow region 301 and parallel to the plane where the circuit board 10 is located.

On this basis, as shown in FIGS. 8 and 9, among two adjacent first slit groups 310, a length of a first slit 311 in any one first slit group 310 is greater than or equal to a length of a connection line between two adjacent first slits 311 in any one first slit group 310.

In this way, there is at least one first slit 311 in any direction on the periphery of the hollow region 301. In this case, the shrinkage stress on the first reflective layer 30 may be released by the first slit(s) 311 in any direction parallel to the plane where the circuit board 10 is located, thereby avoiding the break between adjacent first slits 311 in the first slit group 310 due to excessive shrinkage stress.

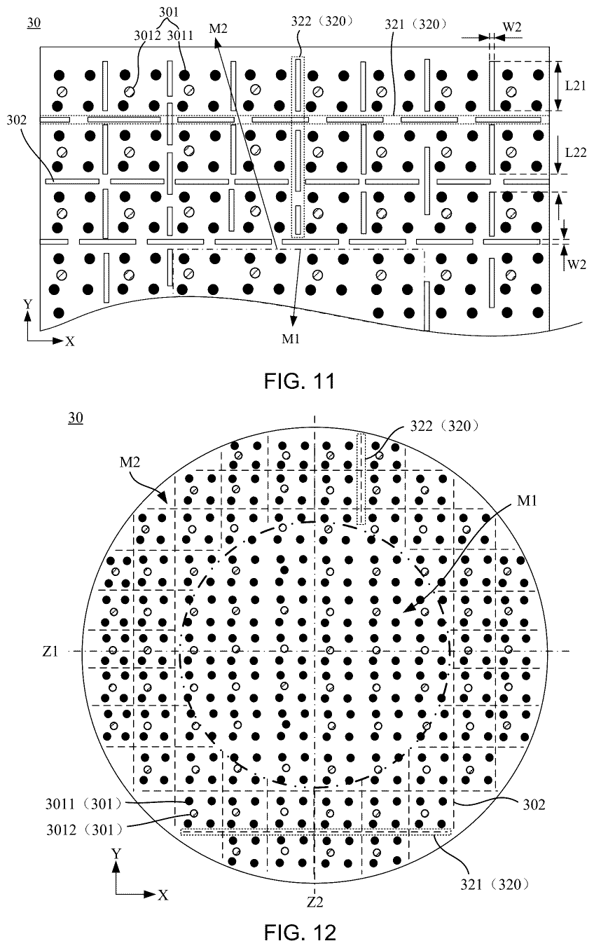

It will be understood that, referring to FIGS. 7 and 11, the first reflective layer 30 shrinks toward the center, and the shrinkage amount at the edge of the first reflective layer 30 is large. Based on this, the first reflective layer 30 includes a central region M1 and an edge region M2 surrounding the central region M1. The first reflective layer 30 further includes a second slit group 320 disposed in the edge region M2. The second slit group 320 includes a plurality of second slits 302 arranged at intervals. The second slit 302 is located between two adjacent electronic components 20. It will be noted that a shape of a boundary line between the central region M1 and the edge region M2 is similar to the shape of the first reflective layer 30.

In this case, both the central region M1 and the edge region M2 of the first reflective layer 30 may shrink and deform at the plurality of second slits 302 in the second slit group 320 to release stress, thereby reducing the displacement accumulation of the edge region M2 of the first reflective layer 30 and reducing the shrinkage amount of the edge region M2 of the first reflective layer 30. Therefore, the stretching of the circuit board 10 by the edge region M2 of the first reflective layer 30 is reduced, and the warpage of the circuit board 10 (light-emitting substrate 110) is reduced. In addition, the risk of a part of the edge region M2 of the first reflective layer 30 interfering with the electronic component 20 and the cracking in the encapsulation portion 50 is reduced, the risk of failure of the electronic component 20 is reduced, and the product yield is improved.

In addition, when the maximum length of the first reflective layer 30 is less than or equal to a preset value, the shrinkage amount of the edge of the first reflective layer 30 is less than 0.1 mm. When the maximum length of the first reflective layer 30 is greater than the preset value, the shrinkage amount of the edge of the first reflective layer 30 increases proportionally.

Based on this, a region where the maximum length of the first reflective layer 30 is less than or equal to the preset value may be, for example, the central region M1, and a region where the maximum length of the first reflective layer 30 is greater than the preset value may be, for example, the edge region M2.

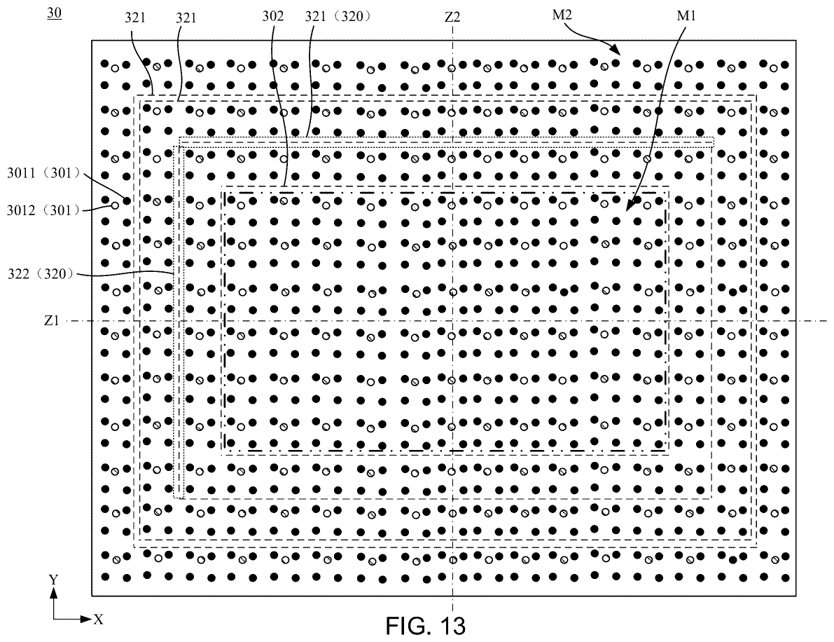

For example, referring to FIGS. 7 and 12, a radial length of a figure enclosed by the boundary line between the edge region M2 and the central region M1 is greater than or equal to 300 mm.

For example, as shown in FIG. 12, the first reflective layer 30 is substantially in a shape of a circle, and the radial length of the figure enclosed by the boundary line between the edge region M2 and the central region M1 is 300 mm. In this case, the central region M1 is a circle with a diameter of 300 mm, and the edge region M2 is a circular ring outside the central region M1, and an inner diameter of the circular ring is 300 mm.

As another example, as shown in FIGS. 13, 14 and 15, the first reflective layer 30 is substantially in a shape of a rectangle, the figure enclosed by the boundary line between the edge region M2 and the center region M1 may also be in a shape of a rectangle, a length of the rectangle is 600 mm, and a width of the rectangle line is 300 mm. In this case, the central region M1 is a rectangle with a length of 600 mm and a width of 300 mm, and the edge region M2 is a frame outside the central region M1, and an inner side of the frame has a length of 600 mm and a width of 300 mm.

Some embodiments of the present disclosure will be illustrated below by taking an example in which the first reflective layer 30 is substantially in a shape of a rectangle. However, the embodiments of the present disclosure are not limited thereto. The first reflective layer 30 may also be in any other shape as long as the same technical concept is applied.

Referring to FIG. 11, the second slit 302 is substantially in a shape of a rectangle. It will be understood that the larger the length L21 of the second slit 302 is, the better the stress release effect is. The larger the length L22 of the connection line of two adjacent second slits 302 is, the lower the risk of the first reflective layer 30 being broken is.

Based on this, referring to FIG. 11, a ratio of a length L21 of a second slit 302 to a length L22 of a connection line between another second slit 302 adjacent to the second slit 302 is in a range of 2 to 3. In this case, the structural strength between two adjacent second slits 302 is relatively large, the risk of the first reflective layer 30 being broken is relatively low, and the stress release effect of the plurality of second slits 302 in the second slit group 320 is relatively good. In this way, the shrinkage amount of the edge region M2 of the first reflective layer 30 may be greatly reduced without breaking the first reflective layer 30. Furthermore, the stretching of the circuit board 10 by the edge region M2 of the first reflective layer 30 is reduced, and the warpage of the circuit board 10 (light-emitting substrate 110) is reduced. In addition, the risk of a part of the edge region M2 of the first reflective layer 30 interfering with the electronic component 20 and the cracking in the encapsulation portion 50 is avoided.

For example, as shown in FIG. 11, the length L21 of the second slit 302 is in a range of 2 mm to 5 mm. For example, the length L21 of the second slit 302 is substantially any one of 2 mm, 2.2 mm, 2.4 mm, 2.5 mm, 2.8 mm, 3 mm, 3.3 mm, 3.5 mm, 3.8 mm, 4 mm, 4.2 mm, 4.5 mm, 4.8 mm, and 5 mm.

For example, as shown in FIG. 11, the length L22 of the connection line between the second slit 302 and another second slit 302 adjacent to the second slit 302 is in a range of 0.7 mm to 2.5 mm. For example, the length L22 of the connection line between the second slit 302 and another second slit 302 adjacent to the second slit 302 is any one of 0.7 mm, 0.8 mm, 1 mm, 1.1 mm, 1.2 mm, 1.5 mm, 1.8 mm, 2 mm, 2.2 mm, and 2.5 mm.

In addition, referring to FIG. 11, the larger the width W2 of the second slit 302 is, the better the stress release effect is. The smaller the width W2 of the second slit 302 is, the lower the risk of the first reflective layer 30 being broken is.

Based on this, as shown in FIG. 11, the width W2 of the second slit 302 is in a range of 0.05 mm to 0.2 mm. For example, the width W2 of the second slit 302 is any one of 0.05 mm, 0.06 mm, 0.07 mm, 0.08 mm, 0.1 mm, 0.11 mm, 0.12 mm, 0.14 mm, 0.15 mm, 0.17 mm and 0.2 mm, so as to realize a good stress release effect without breaking the first reflective layer 30.

In some embodiments, referring to FIG. 7, the plurality of electronic components 20 include a plurality of light-emitting devices 21, the plurality of light-emitting devices 21 are arranged in a plurality of rows and a plurality of columns, each row includes at least two light-emitting devices 21 arranged in a row direction X, and each column includes at least two light-emitting devices 21 arranged in a column direction Y. That is, referring to FIGS. 7 and 11, the first hollow regions 3011 are arranged in a plurality of rows and a plurality of columns, each row includes at least two first hollow regions 3011 arranged in the row direction X, and each column includes at least two first hollow regions 3011 arranged in the column direction Y.

The plurality of second slits 302 of the second slit group 320 are located between two adjacent rows of light-emitting devices 21 or between two adjacent columns of light-emitting devices 21, i.e., located between two adjacent rows of first hollow regions 3011 or between two adjacent columns of first hollow regions 3011. In this way, since two adjacent rows of light-emitting devices 21 or two adjacent columns of light-emitting devices 21 have a large gap therebetween, the plurality of second slits 302 of the second slit group 320 are arranged in the row direction X between two adjacent rows of light-emitting devices 21, or arranged in the column direction Y between two adjacent columns of light-emitting devices 21, which is conducive to reducing the process difficulty of forming the second slit group 320.

For example, as shown in FIG. 7, the light-emitting substrate 110 includes a plurality of light-emitting units 130, and the light-emitting unit 130 includes a plurality of light-emitting devices 21 that are connected in series and/or in parallel and at least one microchip 22. For example, the light-emitting unit 130 includes four light-emitting devices 21 connected in series and one microchip 22. Of course, the light-emitting unit 130 may also include five, six, seven or eight light-emitting devices 21. The connection of the plurality of light-emitting devices 21 in the light-emitting unit 130 is not limited to series connection, and it may also be parallel connection, which will not be limited in the embodiments of the present disclosure.

On this basis, as shown in FIG. 7, the plurality of second slits 302 of the second slit group 320 may be located between two adjacent light-emitting units 130. In this way, the shrinkage deformation of the first reflective layer 30 at each light-emitting unit 130 is substantially the same, so that the distribution of the light-emitting center of each light-emitting unit 130 is substantially the same. Therefore, the uniformity of the brightness distribution of the display apparatus 1000 (see FIG. 1) is improved, and the display effect is improved.

In some embodiments, as shown in FIGS. 7 and 11, the first reflective layer 30 includes a plurality of second slit groups 320, and the plurality of second slit groups 320 are divided into a plurality of row slit groups 321 and a plurality of column slit groups 322. Furthermore, the row slit group 321 is located between two adjacent rows of light-emitting devices 21, and the column slit group 322 is located between two adjacent columns of light-emitting devices 21.

It will be understood that the shrinkage stress on the first reflective layer 30 may be mainly decomposed into the shrinkage stress in the row direction X and the shrinkage stress in the column direction Y. The shrinkage stress in the row direction X may be released by a plurality of second slits 302 of the column slit groups 322, thereby reducing the displacement accumulation of the edge region M2 of the first reflective layer 30 in the row direction X. The shrinkage stress in the column direction Y may be released by a plurality of second slits 302 of the row slit groups 321, thereby reducing the displacement accumulation of the edge region M2 of the first reflective layer 30 in the column direction Y. In this way, it may be possible to further reduce the shrinkage amount of the edge region M2 of the first reflective layer 30, and in turn further reduce the warpage of the circuit board 10 (light-emitting substrate 110). In addition, the risk of a part of the edge region M2 of the first reflective layer 30 interfering with the electronic component 20 and the cracking in the encapsulation portion 50 is further reduced.

It will be noted that one row slit group 321 or multiple row slit groups 321 may be arranged between two adjacent rows of light-emitting devices 21, and one column slit group 322 or multiple column slit groups 322 may be arranged between two adjacent columns of light-emitting devices 21.

Referring to FIG. 13, in the case where one row slit group 321 is arranged between two adjacent rows of light-emitting devices 21 (four row slit groups 321 relatively close to the center region M1 in FIG. 13) and one column slit group 322 is arranged between two adjacent columns of light-emitting devices 21 (four column slit groups 322 relatively close to the center region M1 in FIG. 13), distances between the second slit group 320 and the two adjacent rows or columns of hollow regions 301 are substantially equal, so that the shrinkage amounts at two rows or columns of hollow regions 301 adjacent to the second slit group 320 are substantially equal, which is conducive to improving the uniformity of the brightness distribution of the light-emitting substrate 110.

Referring to FIG. 13, in the case where multiple row slit groups 321 (four row slit groups 321 relatively far away from the central region M1 in FIG. 13) are arranged between two adjacent rows of light-emitting devices 21 and multiple column slit groups 322 (four column slit groups 322 relatively far away from the central region M1 in FIG. 13) are arranged between two adjacent columns of light-emitting devices 21, the multiple row slit groups 321 are symmetrical about an axis between the two adjacent rows of light-emitting devices 21, and the multiple column slit groups 322 are symmetrical about an axis between the two adjacent columns of light-emitting devices 21. In this way, the shrinkage amounts of the two rows or columns of the hollow regions 301 adjacent to the second slit group 320 are substantially equal, which is conducive to improving the uniformity of the brightness distribution of the light-emitting substrate 110.

The embodiments of the present disclosure will be illustrated below by taking an example in which one row slit group 321 is arranged between two adjacent rows of light-emitting devices 21 and one column slit group 322 is arranged between two adjacent columns of light-emitting devices 21. However, the embodiments of the present disclosure are not limited thereto.

In addition, referring to FIGS. 13, 14 and 15, the first reflective layer 30 has a first axis Z1 extending in the row direction X and a second axis Z2 extending in the column direction Y. Furthermore, a plurality of row slit groups 321 are symmetrical about the first axis Z1, and a plurality of column slit groups 322 are symmetrical about the second axis Z2. In this way, the shrinkage amounts of both sides of the first reflective layer 30 in the row direction X are substantially equal, the shrinkage deformation of hollow regions 301 symmetrically about the first axis Z1 is substantially the same, and the shrinkage deformation of hollow regions 301 symmetrically about the second axis Z2 is substantially the same, which is conducive to improving the uniformity of the brightness distribution of the light-emitting substrate 110.

It will be understood that, referring to FIGS. 13, 14 and 15, a distance between two ends far away from each other of second slits 302 that are located at two ends of the second slit group 320 may be less than a distance between two ends far away from each other of an adjacent row or column of hollow regions 301 located in the edge region M2, or may be greater than or equal to the distance between two ends far away from each other of the adjacent row or column of hollow regions 301 located in the edge region M2.

For example, as shown in FIG. 13, in the first reflective layer 30, a distance between two ends far away from each other of second slits 302 that are located at two ends of each second slit group 320 is less than a distance between two ends far away from each other of an adjacent row or column of hollow regions 301 located in the edge region M2. For example, as shown in FIG. 13, among the plurality of second slit groups 320, ends of row slit groups 321 and ends of column slit groups 322 intersect, so as to surround the central region M1. In this way, the first reflective layer 30 has high strength and low risk of breakage.

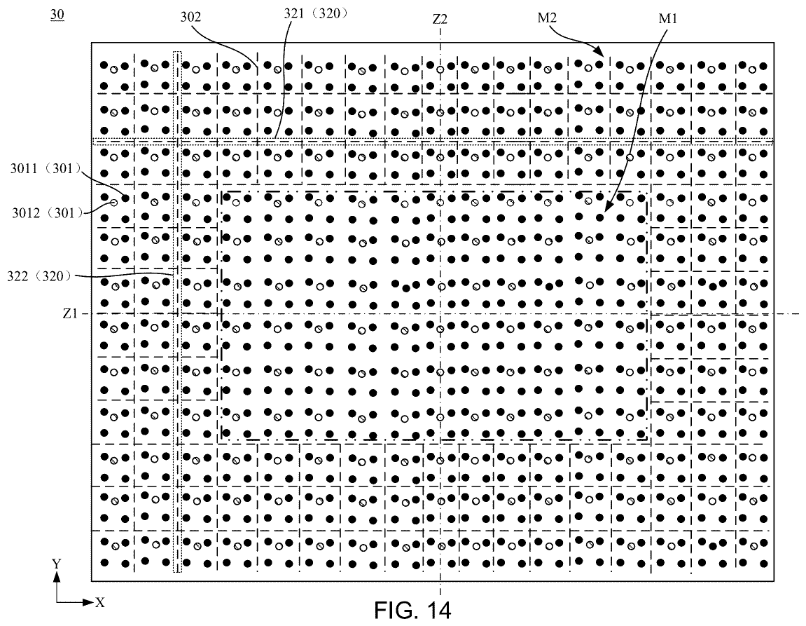

For example, as shown in FIG. 14, in the first reflective layer 30, a distance between two ends far away from each other of second slits 302 that are located at two ends of each second slit group 320 is greater than or equal to a distance between two ends far away from each other of an adjacent row or column of hollow regions 301 located in the edge region M2. In this way, the stress release effect of the edge region M2 of the first reflective layer 30 is good, and the process is simple.

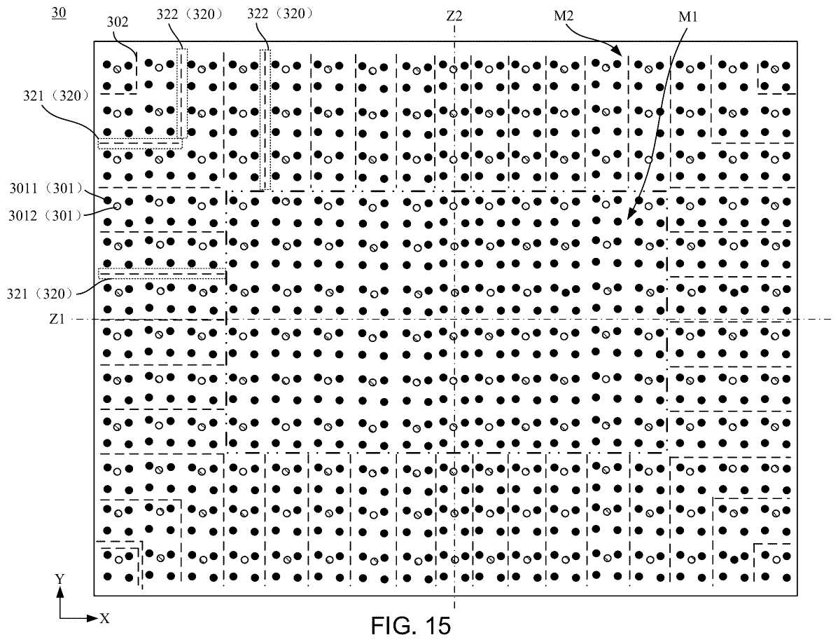

For example, as shown in FIG. 15, in the first reflective layer 30, a distance between two ends far away from each other of second slits 302 that are located at two ends of each of a part of second slit groups 320 is less than a distance between two ends far away from each other of an adjacent row or column of hollow regions 301 located in the edge region M2; and a distance between two ends far away from each other of second slits 302 that are located at two ends of each of another part of second slit groups 320 is greater than or equal to a distance between two ends far away from each other of an adjacent row or column of hollow regions 301 located in the edge region M2. In this way, the first reflective layer 30 has high strength and lower risk of breakage, and the stress release effect of the edge region M2 of the first reflective layer 30 is good.

In some embodiments, referring to FIGS. 11 and 14, along a second direction, a connection line between two adjacent second slits 302 in any second slit group 320 is arranged opposite to a second slit 302 in at least one second slit group 320. For example, among two adjacent second slit groups 320, a connection line between two adjacent second slits 302 in one second slit group 320 is arranged opposite to a second slit 302 in the other second slit group 320. The second direction is perpendicular to the second slits 302 in the second slit group 320 and parallel to the plane where the circuit board 10 is located.

On this basis, as shown in FIG. 11, among two adjacent second slit groups 320, a length of a second slit 302 in any one second slit group 320 is greater than or equal to a length of a connection line between two adjacent second slits 302 in any one second slit group 320.

In this way, the shrinkage stress on a region between two adjacent second slits 302 in any one second slit group 320 may be released by a corresponding second slit 302 in another adjacent second slit group 320, thereby preventing the region between two adjacent second slits 302 in the second slit group 320 of the first reflective layer 30 from being locally subjected to excessive shrinkage stress and causing breakage.

In summary, a distance between the hollow region 301 of the first reflective layer 30 and the electronic component 20 may be reduced by 0.3 mm, and the luminous efficiency of the light-emitting substrate 110 may be increased by 10%.

In some embodiments, referring to FIGS. 3 and 10, the light-emitting substrate 110 further includes a second reflective layer 60, and the second reflective layer 60 is disposed between the first reflective layer 30 and the circuit board 10. The second reflective layer 60 may be directly disposed on the circuit board 10 by using a coating process.

It will be noted that a material of the second reflective layer 60 may include white ink and/or silicon-based white glue. For example, the material of the second reflective layer 60 may include resin (e.g., epoxy resin, or polytetrafluoroethylene resin), titanium dioxide (TiO₂) and an organic solvent (e.g., dipropylene glycol methyl ether).

In addition, as shown in FIG. 10, the second reflective layer 60 is provided therein with a plurality of openings 601; an orthogonal projection of an electronic component 20 on the circuit board 10 is located in an opening 601; and an orthogonal projection of the opening 601 on the circuit board 10 is located in a hollow region 301.

For example, in a direction perpendicular to a boundary of the opening 601 and parallel to the plane where the circuit board 10 is located, a ratio of a length of the opening 601 to a length of the hollow region 301 is in a range of 0.15 to 0.30.

In this case, the light emitted by the light-emitting device 21 toward the hollow region 301 and the opening 601 may be reflected by the second reflective layer 60 to the display panel 200, thereby further improving the light extraction efficiency of the substrate 210 and improving the display effect.

In some embodiments, as shown in FIG. 3, the backlight module 100 further includes a plurality of support pillars 70. The plurality of support pillars 70 are arranged at intervals and, for example, may be arranged in a plurality of rows and a plurality of columns. The support pillars 70 are used to provide an optical distance (OD) required by the backlight module 100. That is, ends of the support pillars 70 are abutted on the light-emitting substrate 110, and another ends of the support pillars 70 are abutted on a surface of an optical film closest to the light-emitting substrate 110 among the plurality of optical films 120. Therefore, there is a mixing distance between the first reflective layer 30 in the light-emitting substrate 110 and the optical film 120. As a result, the light shadow produced by the light-emitting substrate 110 is ameliorated, and the display quality of the display apparatus 1000 is enhanced.

It will be noted that the support pillar 70 may be in a shape of any one of a pyramid, a prism, a cone, a cone frustum and a cylinder, which will not be specifically limited in the embodiments of the present disclosure.

On this basis, the first reflective layer 30 may also be provided therein with a plurality of through holes (not shown in FIG. 3). The through holes are used to correspond to regions where the support pillars 70 are arranged on the light-emitting substrate 110. The arrangement of the through holes is at least the same as the arrangement of the support pillars 70 on the light-emitting substrate 110. Furthermore, the through hole does not interfere with any of the first slit group 310, the second slit group 320 and the hollow region 301.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A light-emitting substrate, comprising:
a circuit board;
an electronic component disposed on the circuit board;
a first reflective layer disposed on the circuit board, wherein the first reflective layer includes a hollow region and a first slit group arranged around the hollow region; an orthogonal projection of the electronic component on the circuit board is located within an orthogonal projection of the hollow region on the circuit board; the first slit group includes a plurality of first slits arranged at intervals; a sum of a length of a first slit and a length of a connection line between the first slit and another first slit adjacent to the first slit is a first length; a ratio of the first length to a perimeter of a first closed figure is in a range of 1/4 to 1/3; and the first closed figure is composed of the plurality of first slits belonging to the same first slit group that are connected end to end in a clockwise or counterclockwise direction; and
a first bonding layer disposed on a surface of the first reflective layer close to the circuit board.

2. The light-emitting substrate according to claim 1, wherein a ratio of the length of the first slit to the length of the connection line between the first slit and the another first slit adjacent to the first slit is in a range of 2 to 3.

3. The light-emitting substrate according to claim 1, wherein the first reflective layer includes a plurality of first slit groups, and at least two first slit groups are arranged around a same hollow region.

4. The light-emitting substrate according to claim 3, wherein geometric centers of at least two first closed figures corresponding to the at least two first slit groups arranged around the same hollow region coincide with a geometric center of the hollow region.

5. The light-emitting substrate according to claim 3, wherein a distance between two first closed figures corresponding to any two adjacent first slit groups is a first distance; among the at least two first slit groups arranged around the same hollow region, a distance between a first slit group closest to the hollow region and the hollow region is a second distance; and the first distance is substantially equal to the second distance.

6. The light-emitting substrate according to claim 3, wherein a distance between two first closed figures corresponding to any two adjacent first slit groups is a first distance, and the first distance is greater than or equal to 0.5 mm.

7. The light-emitting substrate according to claim 3, wherein along a first direction, a connection line between two adjacent first slits in any first slit group is arranged opposite to a first slit in at least one first slit group, the first direction being perpendicular to a boundary of the hollow region and parallel to a plane where the circuit board is located.

8. The light-emitting substrate according to claim 7, wherein among two adjacent first slit groups, a length of a first slit in any one first slit group is greater than or equal to a length of a connection line between two adjacent first slits in any one first slit group.

9. The light-emitting substrate according to claim 1, wherein an outer boundary of the orthogonal projection of the hollow region on the circuit board is a second closed figure; and the first closed figure and the second closed figure are similar.

10. The light-emitting substrate according to claim 1, wherein the first closed figure is in a shape of any one of a circle, an ellipse and a polygon, and the second closed figure is in a shape of any one of a circle, an ellipse and a polygon.

11. The light-emitting substrate according to claim 1, wherein the light-emitting substrate comprises a plurality of electronic components including a plurality of light-emitting devices, and the plurality of light-emitting devices are arranged in a plurality of rows and a plurality of columns; the first reflective layer includes a central region and an edge region surrounding the central region;
the first reflective layer further includes a second slit group disposed in the edge region, the second slit group includes a plurality of second slits arranged at intervals, and the plurality of second slits are located between two adjacent rows of light-emitting devices or two adjacent columns of light-emitting devices.

12. The light-emitting substrate according to claim 11, wherein a ratio of a length of a second slit to a length of a connection line between the second slit and another second slit adjacent to the second slit is in a range of 2 to 3.

13. The light-emitting substrate according to claim 11, wherein the first reflective layer includes a plurality of second slit groups, and the plurality of second slit groups are divided into a plurality of row slit groups and a plurality of column slit groups; and a row slit group is located between two adjacent rows of light-emitting devices, and a column slit group is located between two adjacent columns of light-emitting devices.

14. The light-emitting substrate according to claim 13, wherein the first reflective layer has a first axis extending in a row direction and a second axis extending in a column direction, the plurality of row slit groups are symmetrical about the first axis, and the plurality of column slit groups are symmetrical about the second axis.

15. The light-emitting substrate according to claim 11, wherein the first reflective layer includes a plurality of hollow regions arranged in rows and columns, and a distance between two ends far away from each other of second slits that are located at two ends of the second slit group is greater than or equal to a distance between two ends far away from each other of an adjacent row or column of hollow regions located in the edge region.

16. The light-emitting substrate according to claim 11, wherein the first reflective layer includes a plurality of second slit groups; and along a second direction, a connection line between two adjacent second slits in any second slit group is arranged opposite to a second slit in at least one second slit group, the second direction being perpendicular to the second slits in the second slit group.

17. The light-emitting substrate according to claim 16, wherein among two adjacent second slit groups, a length of a second slit in any one second slit group is greater than or equal to a length of a connection line between two adjacent second slits in any one second slit group.

18. The light-emitting substrate according to claim 11, wherein distances between the second slit group and two adjacent rows or columns of hollow regions are substantially equal; and/or
a radial length of a figure enclosed by a boundary line between the edge region and the central region is greater than or equal to 300 mm.

19. (canceled)

20. A backlight module, comprising:
the light-emitting substrate according to claim 1, the light-emitting substrate having a light-exit side and a non-light-exit side opposite to each other; and
a plurality of optical films disposed on the light-exit side of the light-emitting substrate.

21. A display apparatus, comprising: the backlight module according to claim 20; and
a display panel disposed on a side of the plurality of optical films in the backlight module away from the light-emitting substrate.
